(19) United States
(12) Patent Application Publication
(10) Pub. No.: US 2008/0017350 A1
(43) Pub. Date: Jan. 24, 2008

(54) HEAT SINK

(75) Inventors: Ching-Bai Hwang, Tu-Cheng (TW); Zhi-Jian Li, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,292

(22) Filed: Jul. 21, 2006

(51) Int. Cl. H05K 7/20

(52) U.S. Cl. 165/80.3; 165/121; 165/104.33; 165/182; 361/700

(57) ABSTRACT

A heat sink includes a fin unit (10) and a heat pipe (40) for transferring heat from a heat-generating device to the fin unit. The fin unit includes a plurality of fins (20) parallel to each other. A flow channel (23) is defined between any of two neighboring fins for an airflow flowing therethrough. Each fin defines a through hole (25) having an axis of symmetry which extends along the flowing direction of the airflow. The through hole is for extension of the heat pipe therethrough. A plurality of protrusions (221, 222, 223, 224) extend outwardly from each fin. The protrusions being arranged irregularly around the heat pipe for guiding the airflow flowing to the heat pipe.

### FIELD OF THE INVENTION

The present invention relates generally to a heat sink, and in particular to a heat sink with improved fin structure for achieving a high heat-dissipation efficiency.

### DESCRIPTION OF RELATED ART

With the advance of large scale integrated circuit technology, and the wide spread use of computers in all trades and occupations, in order to meet the required improvement in data processing load and request-response times, high speed processors have become faster and faster, which causes the processors to generate redundant heat. Redundant heat which is not quickly removed will have tremendous influence on the system security and performance. Usually, people install a heat sink on the central processor to assist its heat dissipation, whilst also installing a fan on the heat sink to provide a forced airflow to increase heat dissipation.

FIG. 5 shows a heat sink 1 in accordance with related art. The heat sink 1 comprises a fin unit 2, a heat pipe 4 extending through the fin unit 2, and a cooling fan (not shown) arranged at a side of the fin unit 2 so as to generate an airflow through the fin unit 2. The fin unit 2 comprises a plurality of fins stacked together. Each fin is planar and parallel to each other. A flow channel 3 is formed between two adjacent fins. The heat pipe 4 includes an evaporating section for thermally connecting with a heat-generating electronic device and condensing sections extending into through holes of the fin unit 2 and thermally connecting with the fins.

During operation of the heat-generating electronic device, the heat pipe 4 absorbs heat generated by the heat-generating electronic device. The heat is moved from the evaporating section to the condensing sections and then on to the fins of the fin unit 2. At the same time, the airflow that is generated by the cooling fan flows through the flow channels 3 to exchange heat with the fins. The heat is dissipated to the surrounding environment by the airflow. Thus, heat dissipation of the heat-generating electronic device is accomplished.

For enhancing the heat dissipation effectiveness of this heat sink 1, the heat dissipation area of the fin unit 2 needs to be increased. One way to increase the heat dissipation area of the fin unit 2 is to increase the size of each fin. However, this increases the weight and size of the heat sink, which conflicts with the requirement for light weight and compactness. Another way to increase the heat dissipation area of the fin unit 2 is reducing the spacing distance between adjacent fins, so that the fin unit 2 can accommodate more fins. This way may avoid increasing the volume of heat sink 1, however, reducing the spacing between two adjacent fins of the fin unit 2 will increase the flow resistance, which not only influences the heat dissipation effect but also increases the noise. Also, due to the planar shape of each fin of the fin unit 2, a part of the airflow that is generated by the cooling fan escapes from the fin unit 2 around it's lateral sides, before the airflow reaches the other side of the fin unit that is opposite to the cooling fan. It causes reduction in the heat exchange with the fin unit 2. Therefore, the airflow flowing through the fin unit cannot sufficiently assist heat dissipation from a heat-generating electronic device. Furthermore, due to viscosity, a laminar air envelope may form at the surface of the fin unit 2 when the airflow flows through the fin unit 2. The flowing speed of the airflow in this laminar air envelope is nearly zero, whereby the degree of heat exchange between the airflow and the fin unit 2 is greatly reduced. Accordingly, heat dissipation effectiveness of the conventional heat sink 1 is limited.

What is needed, therefore, is a heat sink having a high heat dissipation effectiveness without increasing the size and the weight of the fin unit.

### SUMMARY OF THE INVENTION

According to a preferred embodiment of the present invention, a heat sink includes a fin unit and a heat pipe for transferring heat from a heat-generating device to the fin unit. The fin unit includes a plurality of fins parallel to each other. A flow channel is defined between any of two neighboring fins for an airflow flowing therethrough. Each fin defines a through hole for extension of the heat pipe therethrough. The through hole has an axis of symmetry which extends along the flowing direction of the airflow. A plurality of protrusions extend outwardly from each fin. The protrusions are arranged irregularly around the heat pipe for guiding the airflow to the heat pipe. The protrusions formed in each fin of the heat sink can guide the distribution and flow direction of the airflow whilst simultaneously enhancing the turbulence on the surface of the fin. Thus the fin unit can have a sufficient heat exchange with the airflow, effectively dissipating the heat of the fin unit that is absorbed from the heat-generating electronic device to the surrounding environment.

Other advantages and novel features of the present invention will be drawn from the following detailed description of the preferred embodiment of the present invention with attached drawings, in which:

### BRIEF DESCRIPTION OF THE DRAWINGS

Many aspects of the present heat sink can be better understood with reference to the following drawings. The components in the drawings are not necessarily drawn to scale, the emphasis instead being placed upon clearly illustrating the principles of the present heat sink. Moreover, in the drawings, like reference numerals designate corresponding parts throughout the several views:

FIG. 1 is an assembled, isometric view of a heat sink in accordance with a preferred embodiment of the present invention and an electric fan;

FIG. 2 is an assembled, isometric view of a fin unit of the heat sink of FIG. 1, with some of fins of the fin unit being omitted for clearly showing structure of the fins;

FIG. 3 is a view similar to FIG. 2, from a different aspect;

FIG. 4 is a top plan view of one of the fins of FIG. 2; and

FIG. 5 is a side view of a heat sink in accordance with related art.

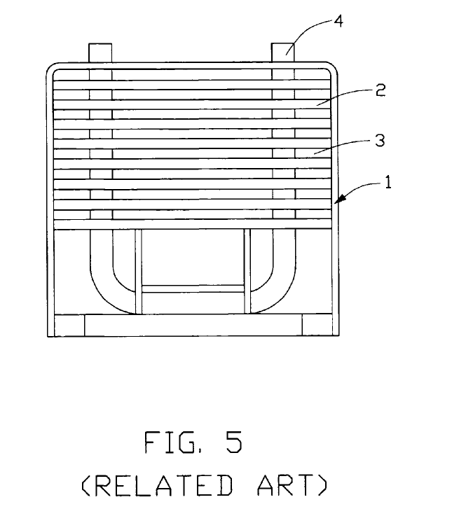

### DETAILED DESCRIPTION OF THE INVENTION

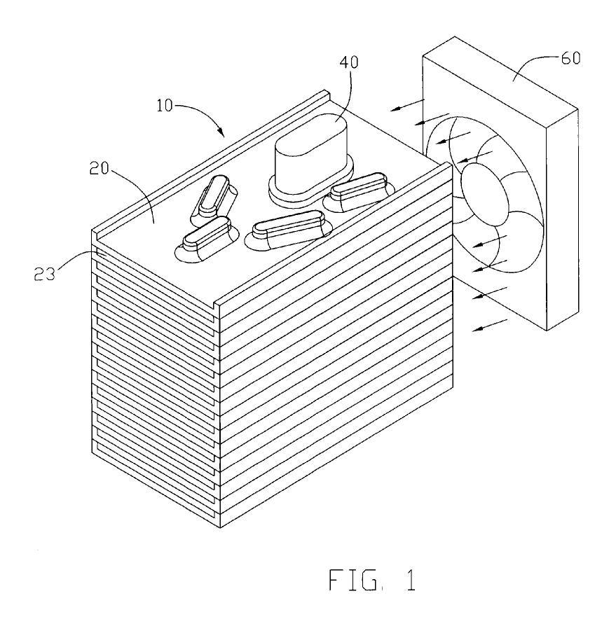

Referring to FIG. 1, a heat sink comprises a fin unit 10, and a heat pipe 40 extending through the fin unit 10. The heat pipe 40 has an evaporating section (not shown) for thermally connecting with a heat source, for example, a central processing unit (CPU, not shown). A cooling fan 60 is arranged at a side of the fin unit 10 for generating an airflow through the fin unit 10 as indicated by arrows.

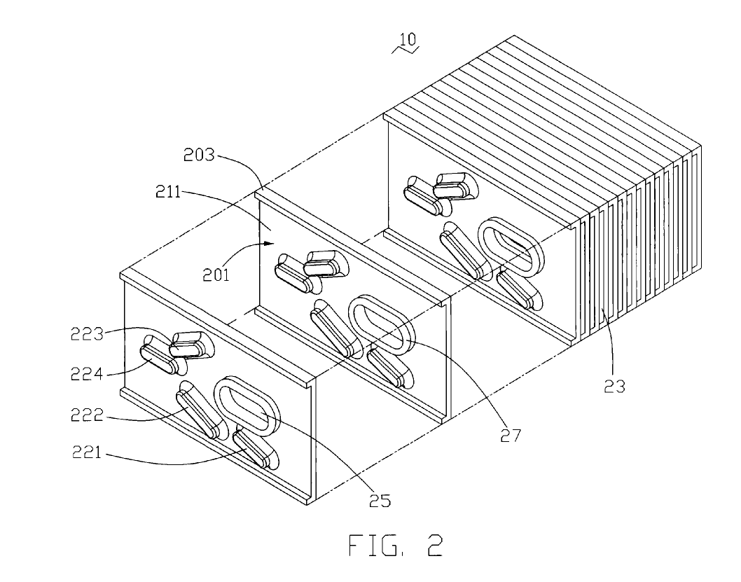

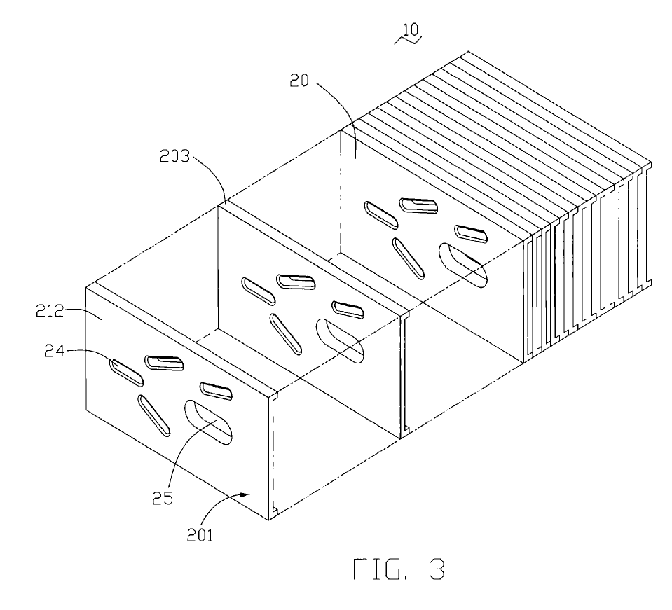

Referring to FIGS. 2-4, the fin unit 10 comprises a plurality of stacked fins 20 parallel to each other. Each fin 20 has a main body 201 which has a reference surface 211 and a base surface 212, and two hems 203 bent from two opposite side edges of the main body 201. Distal edges of the hems 203 of each fin 20 contact with the base surface 212 of an adjacent fin 20, and the height of these hems 203 is thus equal to the distance between the two neighboring fins 20. A flow channel 23 is formed between each two neighboring fins 20 to channel the airflow generated by the fan 60. A through hole 25 is defined in a middle of each fin 20 for receiving the heat pipe 40. The shape and size of the through hole 25 can change according to the heat pipe 40. The through hole 25 in this preferred embodiment of the present invention has nearly an elongated rectangular shape with two arc ends, and the through hole 25 is symmetric to the axis of symmetry X-X which extends along the flowing direction of the airflow. A circle flange 27 extends upwardly from the border of the through hole 25 in the reference surface 211 of each fin 20, and the height of flange 27 is also nearly equal to the distance between two adjacent fins 20. When the fin unit 10 is assembled together, the flange 27 of each fin 20 contacts the border of the through hole 25 in the base surface 212 of an adjacent fin 20. Thus, the through holes 25 cooperatively form a columned space for the heat pipe 40 extending through, and the flanges 27 enclose and contact with the heat pipe 40, which enlarges the contacting surface area between the heat pipe 40 and the fins 20. So, heat absorbed by the heat pipe 40 can be quickly transferred to the fins 20 for further dissipation.

A guiding structure comprises four spaced protrusions, which includes in sequence a first protrusion 221, a second protrusion 222, a third protrusion 223 and a fourth protrusion 224, located around the through hole 25 irregularly and extruding from the reference surface 211 of each fin 20. The protrusions 221, 222, 223, 224 are formed by punching or other means, to simplify manufacturing. A concave 24 corresponding to each of the protrusions 221, 222, 223, 224 is formed in the base surface 212 of the fin 20.

Each of the protrusions 221, 222, 223, 224 is strip-shaped. The first, second, and third protrusions 221, 222, 223 are located at two opposites of the axis X-X, and extend slantwise to the axis X-X. Also these slantwise protrusions (first, second, and third protrusions 221, 222, 223) are nonparallel to each other. The slantwise protrusions extend along the flowing direction of the airflow from a peripheral portion near the hems 203 of the fin 20 to a central portion defining the through hole 25 therein. An inclined angle smaller than 90 degree is defined between each slantwise protrusion and the axis X-X. As the slantwise protrusions are arranged nonparallel to each other, their inclined angles defined between the axis X-X and the slantwise protrusions are different from each other. The slantwise protrusions define a tapered space therebetween in which the heat pipe 40 is located. The space decreases gradually along the flowing direction of the airflow and is capable of guiding the airflow to flow to and concentrate at the area near to the heat pipe 40 in each fin 20.

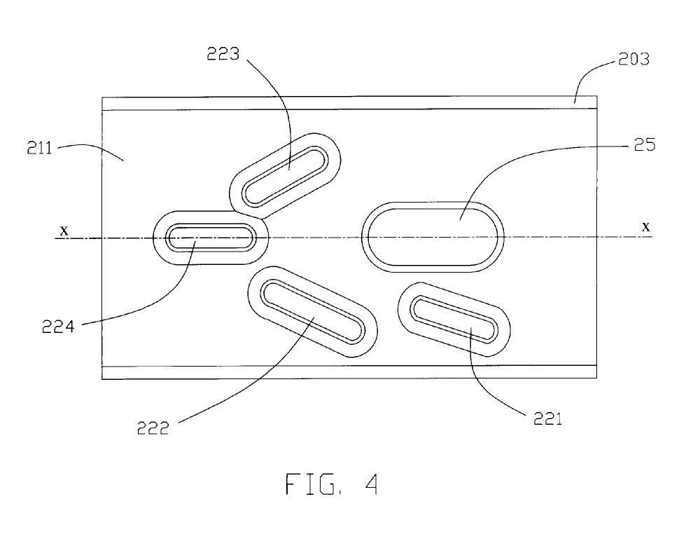

The first and second protrusions 221, 222 are located at a lower side of the axis X-X, and the third protrusion 223 is arranged on an upper side of the axis X-X (as shown in FIG. 4). In other words, the slantwise protrusions are arranged on two opposite sides of the axis X-X unevenly. The first protrusion 221 is located approximately under the through hole 25. The second and third protrusions 222, 223 are relatively far from the through hole 25, and are located approximately at a leeward side of the through hole 25 which is at a left side of the through hole 25 in FIG. 4. The fourth protrusion 224 extends along the flowing direction and is arranged on the axis X-X and located at the leeward side of the through hole 25 of the fin 20. In other words, most of the protrusions 221, 222, 223, 224 are arranged on the leeward side of the through hole 25 of the fin 10.

The heat pipe 40 further comprises a condensing section (not labeled) extending in the through holes 27 of the fins 20. The condensing section thermally connecting with the fins 20 at the flanges 27. Because of the fast heat conductive capacity of the heat pipe 40 and enlarged contacting surface area between the heat pipe 40 and the fins 20, heat is conducted from heat pipe 40 to fins 20 effectively and evenly.

During the operation of the heat-generating electronic device, the evaporating section of the heat pipe 40 absorbs heat generated by the heat source. The working fluid that is contained in the inner side of the heat pipe 40 absorbs heat and evaporates substantially and moves to the condensing section. Evaporated working fluid is cooled at the condensing section and condensed, the heat is thus released. Finally, the condensed working fluid flows back to the evaporating section to begin another cycle. By this way, the working fluid absorbs/releases amounts of heat. The heat generated by the heat-generating electronic device is thus transferred from the heat pipe 40 to the fins 20 almost immediately.

As the fins 20 have heat resistance, a hot area is formed around the through holes 27, where it is adjacent to the heat pipe 40 in each fin 20. Particularly to the left portion around the through hole 25 of the fin 20 located at the leeward side of the through hole 25, the airflow can not flow thereto directly due to the obstruction of the heat pipe 40 which is received in the through holes 25 of the fin unit 10. The temperature in this hot area is high compared to the rest of the fins 20. After the forced airflow generated by the fan 60 flows into the flow channels 23, the slantwise protrusions 221, 222, 223 guide the airflow to flow to the hot area around the heat pipe 40. Thus the heat in this area can be efficiently carried away by airflow. Furthermore, most of the protrusions 221, 222, 223, 224 are arranged at the leeward side of the heat pipe 40, thus increasing the heat dissipation area of the fin unit 10. As the width of the spaces surrounded by the protrusions 221, 222, 223, 224 decreases gradually along the direction of the airflow, which results in the speed of the airflow being increased to thereby increase heat-dissipating efficiency of the fin unit 10. Due to the influence of viscosity, a laminar air envelope will form on the surface of the each fin 20, when the airflow passes through the flow channel 23, but if the airflow meets a barrier during it's flowing process, a vortex is formed around the barrier. The protrusions 221, 222, 223, 224 act as a barrier arranged in the flow channel 23, destroying the laminar air envelope formed on the surface of each fin 20, causing turbulence in the airflow. In addition, the concaves 24, which are formed corresponding to the protrusions 221, 222, 223, 224 on the base surface 212 of each fin 20, cause the base surface 212 of each fin 20 to be a caved plane, which in turn causes turbulence in the airflow. Heat exchange between the airflow and the fins 20 is improved as a result. The heat-dissipating efficiency of the heat sink is thus increased.

While the invention has been described in connection with what is presently considered to be the most practical and preferred embodiment, it is to be understood that the invention is not limited to the disclosed embodiments, but, on the contrary, is intended to accommodate various modifications and equivalent arrangements. The heat sink in accordance with the preferred embodiment of the present invention comprises the guiding structure which includes four protrusions 221, 222, 223, 224. Preferably, the number, the size and the shape of these protrusions 221, 222, 223, 224 can change according to the fins 20 and the heat pipe 40. There can be one or more of each of them, and there size can be the same as or different from each other. Also their shape may be dome and the like. It can be understood that the protrusions 221, 222, 223, 224 can have different shapes, for example, some of them are strip-shaped, whilst others can be dome-shaped.

What is claimed is:

1. A heat sink comprising:
a fin unit having a plurality of parallel fins with a flow channel formed between each fin and its neighboring fin for an airflow to flow therethough, a through hole having an axis of symmetry which extends along the flowing direction of the airflow being defined in each of the fins;
at least one heat pipe extending through the through holes of the fins; and
a plurality of protrusions extending outwardly from each fin, the protrusions being arranged irregularly around the heat pipe for guiding the airflow to the heat pipe, wherein at least two of the protrusions are located at opposite sides of the axis of symmetry of the through hole.

2. The heat sink of claim 1, wherein the protrusions have at least one of the following shapes: dome-shaped and strip-shaped.

3. The heat sink of claim 1, wherein the protrusions extend slantwise from a peripheral portion to a middle portion of the fin, an inclined angle smaller than 90 degree is defined between each protrusion and the axis of symmetry of the through hole.

4. The heat sink of claim 3, wherein the protrusions are nonparallel to each other, and the inclined angles defined between the axis and the protrusions are different from each other.

5. The heat sink of claim 3, wherein a tapered space is formed on the surface of each of the fins between the protrusions, a width of the space decreases gradually along the flowing direction of the airflow, and the heat pipe is located in the space.

6. The heat sink of claim 1, wherein the protrusions are arranged at the two opposite sides of the axis of symmetry of the through hole unevenly.

7. The heat sink of claim 1, wherein a number of the protrusions arranged at a leeward side of the through hole of the fin is larger than that of the rest.

8. The heat sink of claim 1, wherein at least one of the protrusions is located on the axis of symmetry of the through hole at a leeward side of the through hole of the fin.

9. The heat sink of claim 1, wherein the protrusions have sizes different from each other.

10. A heat sink, comprising:
a heat pipe;
a plurality of parallel fins stacked along the heat pipe, a flow channel being formed between each fin and its neighboring fin to allow an airflow to flow therethough; and
a plurality of protrusions arranged on each of the fins slantwise to the flowing direction of the airflow, at least one of the protrusions defining an inclined angle with the flowing direction of the airflow different from those of the other protrusions.

11. The heat sink of claim 10, wherein the inclined angles defined between the protrusions and the flowing direction of the airflow are different from each other.

12. The heat sink of claim 10, wherein the protrusions have sizes different from each other.

13. The heat sink of claim 10, wherein each fin defines a through hole for extension of the heat pipe therethrough, a number of the protrusions arranged on each of two opposite sides of an axis of symmetry of the through hole which extends along the flowing direction is different from each other.

14. The heat sink of claim 10, wherein each fin defines a through hole for extension of the heat pipe therethrough, a number of the protrusions arranged at a leeward side of the through hole of the fin is larger than that of the protrusions arranged at a windward side of the through hole of the fin.

15. The heat sink of claim 10, wherein each fin defines a through hole for extension of the heat pipe therethrough, each fin further comprises another protrusion arranged at a leeward side of the through hole and extending along an axis of symmetry of the through hole which extends along the flowing direction of the airflow.

16. A heat sink comprising:
at least a fin;
a heat pipe having a condensing section thermally connecting with the at least a fin substantially at a middle portion of the at least a fin;
a plurality of protrusions formed on the at least a fin, located two opposite sides of the middle portion of the at least a fin and extending slantwise from a periphery of the at least a fin toward the middle portion thereof, wherein the protrusions have ends distant from the condensing section of the heat pipe extending toward each other.

17. The heat sink of claim 16 further comprising a first additional protrusion formed on the at least a fin, the first additional protrusion being located at the middle portion of the at least a fin and farther away from the condensing section of the heat pipe than the plurality of protrusions, the first additional protrusion having an end located between the distant ends of the plurality of protrusions.

18. The heat sink of claim 17 further comprising a second additional protrusion formed on the at least a fin, the second additional protrusion slantwise extending from the periphery of the at least a fin toward the condensing section of the heat pipe, the second additional protrusion having a first end pointing toward an end of the condensing section of the heat pipe near the plurality of protrusions and a second end which is opposite to the first end and points away from the plurality of protrusions.
